(19) United States
(12) Patent Application Publication
(10) Pub. No.: US 2006/0043373 A1
(43) Pub. Date: Mar. 2, 2006

(54) Method for manufacturing a pixel array of top emitting OLED

(75) Inventors: Yung Fu Wu, Zhonghe City (TW); Chun Cheng Cheng, Pingtung City (TW); Yung Hui Yeh, Hsinchu City (TW)

Correspondence Address: BRUCE H. TROXELL;TROXELL LAW OFFICE PLLC, SUITE 1404, 5205 LEESBURG PIKE, FALLS CHURCH, VA, 22041, US

(73) Assignee: Industrial Technology Research Institute

(21) Appl. No.: 10/984,745

(22) Filed: Nov. 10, 2004

(30) Foreign Application Priority Data
Aug. 26, 2004 (TW) 93125420

(51) Int. Cl. H01L 29/04

(52) U.S. Cl. 257/72

(57) ABSTRACT

A process for manufacturing a pixel array of top-emitting OLED pixel is provided. The process comprises: providing a substrate having at least two poly-silicon islands defined thereon, and defining an implantation region on the substrate; forming a gate insulator layer and a gate metal layer sequentially, and then defining a gate; carrying out an implantation process for forming the doped region; forming an inter-layer dielectric (ILD) layer and etching a plurality of contact holes thereon; forming a source/drain metal layer and defining a source/drain pattern thereon; wherein the patterned source/drain metal layer extends to the pixel array of the top-emitting OLED so as to be employed as a bottom electrode of the top-emitting OLED. The characteristic of the present invention is that the bottom electrode is substantially the portion of the source/drain extending to the pixel array of the top-emitting OLED, so that the array manufacturing can save at least two masks.

### FIELD OF THE INVENTION

The present invention relates to a pixel array of organic light emitting diode (OLED) and the method of manufacturing the same, and more particularly, to a pixel array of the top emitting OLED pixel and the method of manufacturing the same employing simplified mask processes for cost reduction.

### BACKGROUND OF THE INVENTION

Display is one of the important output apparatus among the computer peripherals. Recently, the requirements of thinner and lighter computer peripherals have enabled the thin film transistor liquid crystal display (TFT-LCD) and OLED to be widely used. Wherein, OLED are becoming popular technology for applications such as flat panel displays, since, unlike TFT-LCDs, which require backlighting, the OLED display is substantially an emissive device which consist of a hole-injection layer, a hole-transport layer, an emissive layer and an electron-transport layer and when voltage is applied to the OLED cell, the injected positive and negative charges recombine in the emissive layer and create electro luminescent light. By virtue of this, OLED technology is beginning to replace LCD technology in handheld devices such as Personal digital assistant (PDA) and cellular phones because the technology is brighter, thinner, faster and lighter than LCDs, use less power, offer higher contrast and are cheaper to manufacture.

Latest OLED displays are light-emitting devices capable of emitting different colors of light according to the organic material used therein that have no use of backlight module and color filter. In addition, other than the advantages also provided by the TFT-LCDs, such as high contrast (100:1), good graphic quality in both bright and dark environment, full-color capability, large-size and flexibility, the OLEDs also have characteristics much better than that of the TFT-LCDs, such as simple configuration, high durability, low cost, low driving voltage (i.e. about 3˜9V), low power consumption, wide viewing angle (i.e. more than 160°), high brightness (i.e. about 100 cd/m²), and fast response (i.e. 10 μs), etc. In this regard, OLED has a potential to make revolutionary breakthroughs.

FIG. 1 is the schematic representation showing a conventional pixel array of OLED. When a bias voltage V is provided to the OLED for respectively driving electrons and holes to pass through the hole-transport layer 2000a and electron-transport layer 3000a, and then both enter into the organic emissive layer 4000, the electrons and the holes are combined to generate “excitons” while discharging energy and returning to the ground state. Wherein, a portion of the energy is used by the OLED to illuminate, and the other portion (i.e. about 75%) is returned to the ground state in the form of phosphorescence or heat. Because of the radiation materials selected to be used in the OLED having different band gaps, the portion of the energy used by the OLED to illuminate will be released in the form of light of different colors, such that, for OLEDs from which the light emission is only from the bottom of the device, the light of OLED will be radiated from the indium tin oxide (ITO) of the anode 2000 and pass through the glass substrate 1000.

For the purpose of higher resolution and better optical transmission, the recent OLED usually adopts a design of top-emitting. FIG. 2 is a schematic representation showing an improved top-emitting OLED. As distinct from a transparent or bottom-emitting OLED employing ITO as bottom electrode, a top-emitting OLED is one which has a reflective metal layer as the bottom electrode 1300, such that light is produced only out of the top of the device, i.e. the glass substrate 110 through the organic emissive layer 1400 and the top electrode 1200 and not through the bottom electrode 1300.

Please refer to FIG. 3, which is a schematic representation showing a CMOS-TFT process disclosed in the U.S. Pat. No. 6,037,195 by Toshiba. The complicate process of the CMOS-TFT of U.S. Pat. No. 6,037,195 requires nine masks to complete.

In addition, Please refer to FIG. 4, which is a schematic representation showing a P-type TFT used to drive the pixel array of OLED disclosed in the U.S. Pat. No. 6,338,987 by LG. The complicate process of the P-type TFT requires five masks to complete.

Both the P-type thin film transistor and the CMOS transistor require many masks to complete the processes of manufacturing the same, which will adversely affect the manufacturing cost. Thus the present invention provides a pixel array of top-emitting OLED and method of manufacturing the same, which can simplify the process of photolithography by using comparatively less masks and thus reduce the manufacturing cost, increase the product competitiveness.

### SUMMERY OF THE INVENTION

It is the primary object of the present invention to provide a method for manufacturing a pixel array of top-emitting OLED, which can save at least two masks relative to that of the conventional process and thus largely reduce the manufacturing cost.

It is another object of the present invention to provide a method for manufacturing a pixel array of top-emitting OLED, which integrates a top-emitting OLED with the second metal layer of a TFT and is adapted for fabricating a top-emitting OLED display.

It is yet another object of the present invention to provide a pixel array top-emitting OLED, which can function not only without the ITO layer used in a convention OLED for inputting electron holes and downward-transmitting light, but also without the insulator layer along with the contact hole arranged thereon which are sandwiched between the second metal layer and the ITO layer.

In order to achieve the aforesaid objects, the present invention provides a method for manufacturing a pixel array of top-emitting OLED driven by complementary metal-oxide semiconductor (CMOS), comprising the following steps:
a) defining at least two poly-silicon islands and an N+ implantation region on a substrate;
b) forming a gate insulator layer and a gate metal layer sequentially, and then defining a gate;
c) proceeding with an N− implantation for forming a light doped drain (LDD) region;
d) forming a photo resist layer covering areas designated for N-type device while exposing area designated for P-type device preservation to proceed with an P+ implantation;
e) forming an inter-layer dielectric (ILD) layer and then forming a plurality of contact holes thereon by etching;
f) forming a source/drain metal layer while patterning source/drain thereon, wherein the metal of the source/drain extend to the pixel areas of the top-emitting OLED so as to be employed as the bottom electrode of the top-emitting OLED.

In order to achieve the aforesaid objects, the present invention also provides a method for manufacturing a pixel array of top-emitting OLED pixel driven by P-type thin film transistor (TFT), comprising the following steps:
a) defining at least a poly-silicon island on a substrate, and then forming a gate insulator layer and a gate metal layer sequentially thereon while defining a gate thereafter;
b) proceeding with a P+ implantation;
c) forming an inter-layer dielectric (ILD) layer and then forming a plurality of contact holes thereon by etching;
d) forming a source/drain metal layer while patterning source/drain thereon, wherein the metal of the source/drain extend to the pixel areas of the top-emitting OLED so as to be employed as the bottom electrode of the top-emitting OLED.

The present invention further provides a pixel array of a top-emitting OLED, comprising:
a top-emitting OLED, further comprising a top electrode, an organic emissive layer, and a bottom electrode;
a thin film transistor for driving the top-emitting OLED, further comprising at least a source/drain metal layer patterned with at least a source/drain;
wherein, the bottom electrode is substantially the portion of the source/drain extending from the source/drain metal layer to the pixel area of the top-emitting OLED.

### BRIEF DESCRIPTION OF THE DRAWING

FIG. 1 is the schematic representation showing a conventional pixel array of OLED.

FIG. 2 is a schematic representation showing an improved top-emitting OLED.

FIG. 3 is a schematic representation showing a conventional 9-mask-processed CMOS thin film transistor used for driving the pixel array of OLED.

FIG. 4 is the schematic representation showing a conventional 5-mask-processed P-type thin film transistor for driving the pixel array of OLED.

FIG. 5A to FIG. 5H are the schematic illustrations showing the successive procedures for manufacturing a pixel array of a top-emitting OLED driven by P-type thin film transistor with accordance to a preferred embodiment of the present invention.

FIG. 6A to FIG. 6H are the schematic illustrations showing the successive procedures for manufacturing a pixel array of a top-emitting OLED driven by CMOS thin film transistor with accordance to another preferred embodiment of the present invention.

FIG. 7A and 7B are respectively the top views of a conventional pixel array of OLED and the top view of a preferred embodiment of the present invention.

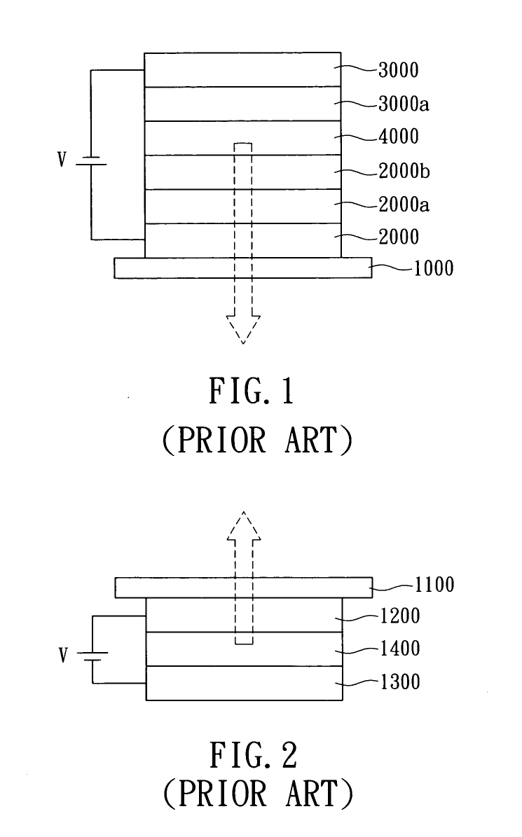

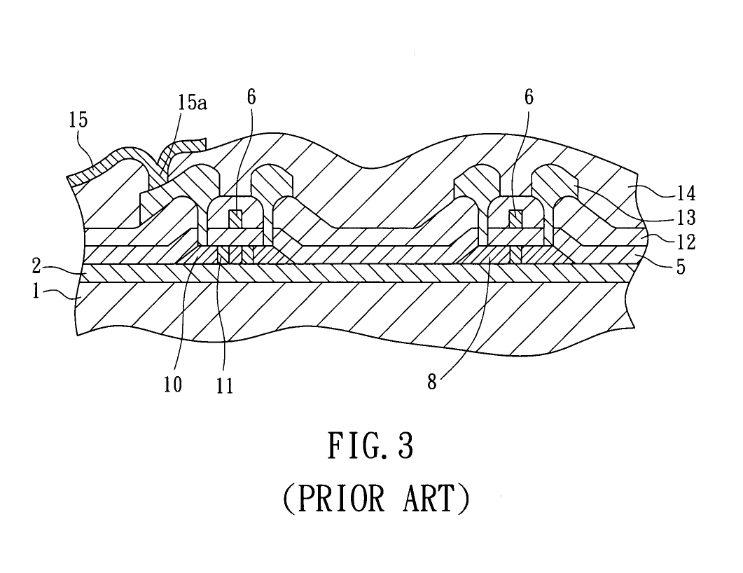

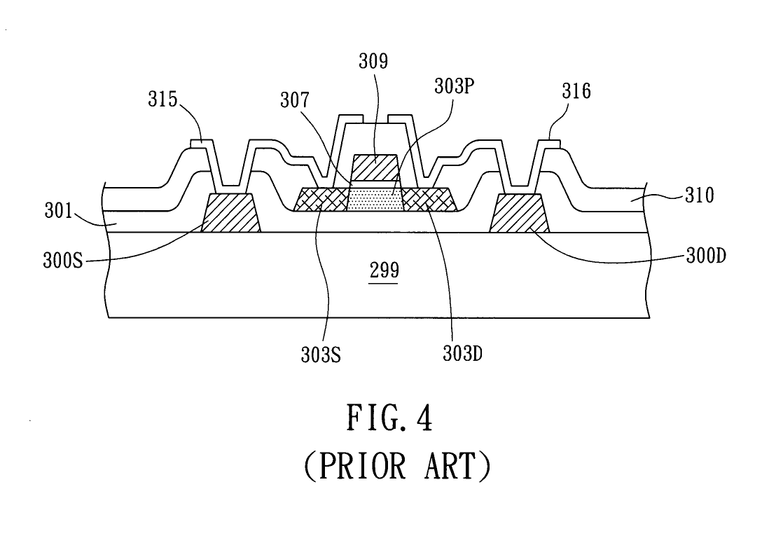

### DETAILED DESCRIPTION OF THE INVENTION

The preferred embodiments disclosed according to the invention are elaborated in conjunction with the drawings attached herein. The technical means disclosed in the present invention is principally applied in areas familiar to those skilled in the art. The drawings attached hereafter are used for illustration purpose, with the aim to facilitate understanding the technical detail involved. Hence, they are by no means used for excluding any other possible embodiments of the present invention.

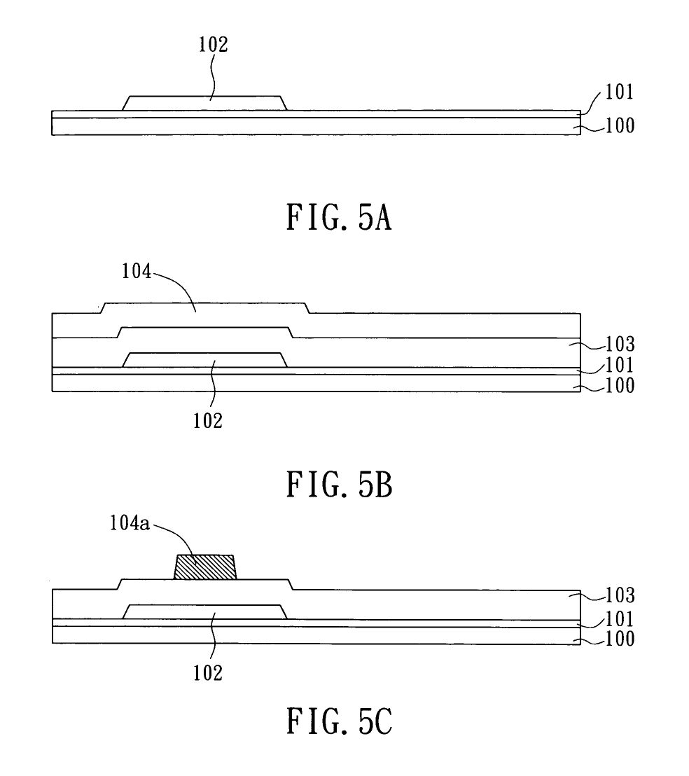

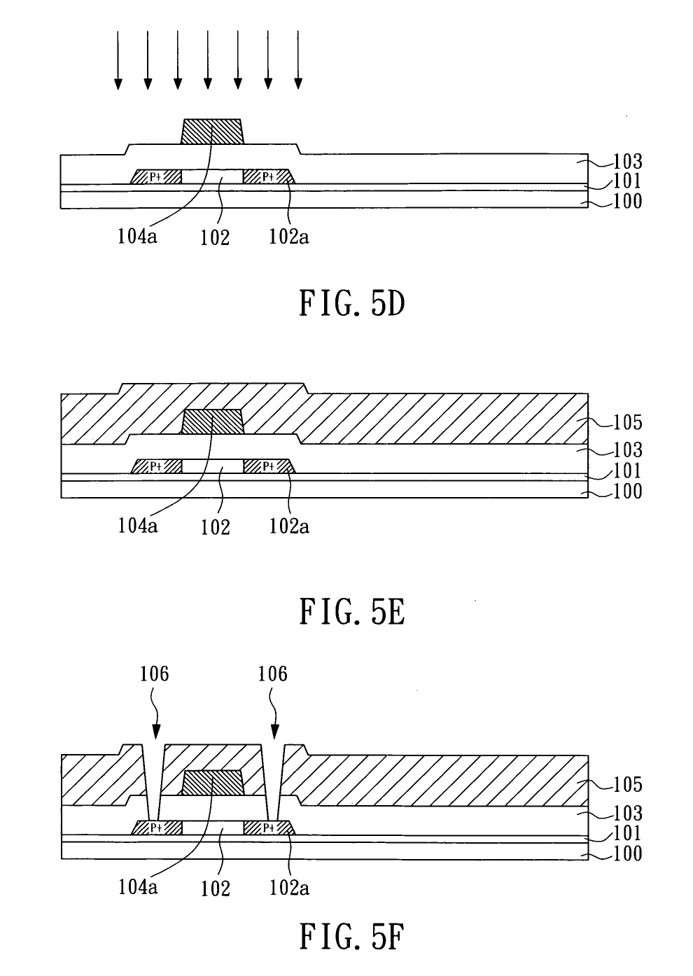

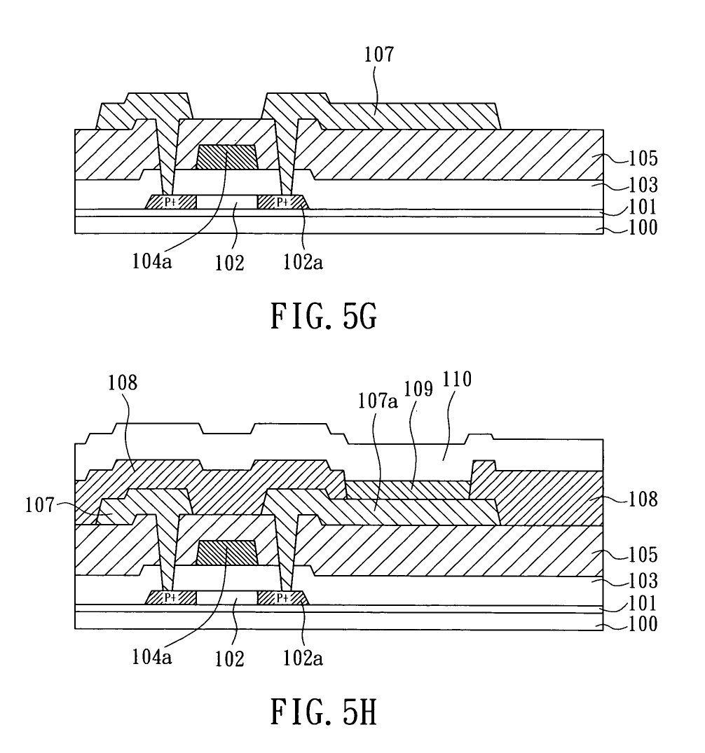

Please refer to FIG. 5A to 5H, which are the schematic illustrations showing the successive procedures for manufacturing a pixel array of a top-emitting OLED driven by P-type thin film transistor with accordance to a preferred embodiment of the present invention.

Firstly, a substrate 100 is provided, and a passive layer 101 and an amorphous silicon layer are sequentially formed over the substrate 100. Afterward, the processes of laser annealing as well as semiconductor ion implantation and so on are carried out to form poly-silicon, and then the photolithography process is carried out to define a poly-silicon island 102 using a first mask, as shown in FIG. 5A. Wherein, the substrate 100 can be made of at least a material selected from the group consisting of glass, plastic, quartz, and silicon crystal.

Next, a gate insulator layer 103, and a metal gate layer 104 are subsequently formed over the substrate 100, and then a gate 104a is defined by a second mask, as shown in FIG. 5C. Wherein, the gate insulator 103 can be the common insulator material used in semiconductor field, such as SiO₂; and the metal gate layer 104 is made of at least a material selected from the group consisting of Nd, Al, Cr, Mo, Cu, and their alloys.

The following step is one of the key points of the present invention. A self-alignment implantation of P⁺ is carried out for defining the P^{+ region 102}a. Wherein, the dopants can be B₂H₆, BF₂⁺, and so on, as shown in FIG. 5D.

As shown in FIG. 5E, an inter-layer dielectric (ILD) layer 105 is formed, and then a plurality of contact holes is etched to the top of the poly-silicon island 102 by using a third mask, as shown in FIG. 5F. Wherein, the material of ILD layer 105 can be any kind of the organic or inorganic insulator material such as SiOx and SiNx.

Please refer to FIG. 5G, the process is the key step of the present invention. A source/drain metal layer is formed and then a source/drain 107 is patterned thereon by a fourth mask. Wherein, the source/drain metal layer is extended to the pixel area of the top-emitting OLED for employing the same as the bottom electrode 107a of the top-emitting OLED. Thus the processes for manufacturing a P-type thin film transistor for driving pixel array of a top-emitting OLED are completed by using only four masks, which is two-mask less comparing to the six-mask process of the conventional method. By virtue of this, the present invention largely simplifying the process and thus saving the manufacturing cost.

Afterward, a passive layer 108 is formed on the portion areas over the ILD layer 105 for the purpose of preventing shorting between the top and bottom electrodes in OLED. Then an organic emissive layer (EML) 109 and an top electrode 110 are sequentially formed over the bottom electrode 107a of source/drain metal layer. Thus, the bottom electrode 107a, the organic emissive layer 109, and the top electrode 110 constitute a top-emitting OLED.

Wherein, the organic emissive layer 109 can be made of any common organic emissive materials, such as small molecule organic dye with high emitting efficiency like Alq3, and organic polymer like PPV, and so on. Moreover, for the purpose of top-emitting OLED, the top electrode 110 must be made of a transparent material, such as indium tin oxide (ITO) and indium zinc oxide (IZO).

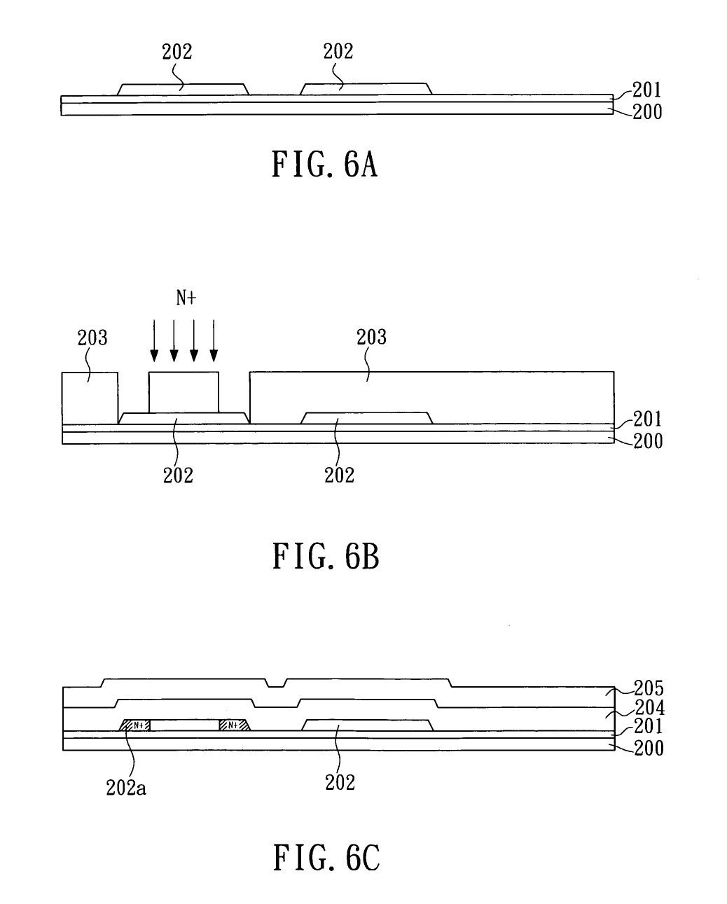

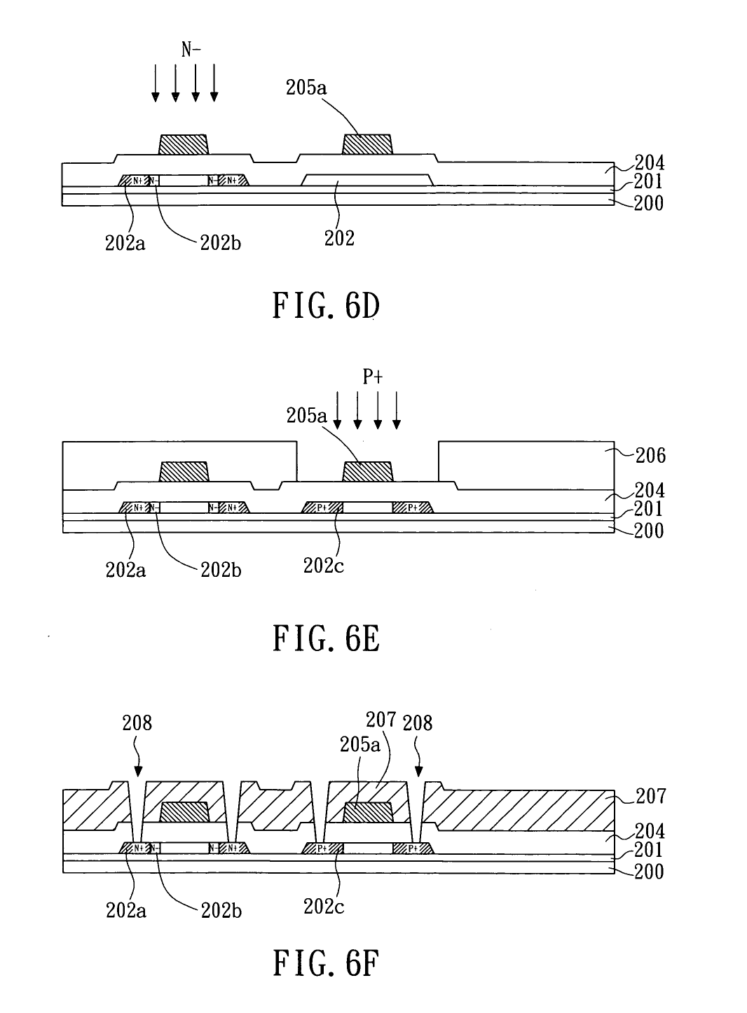

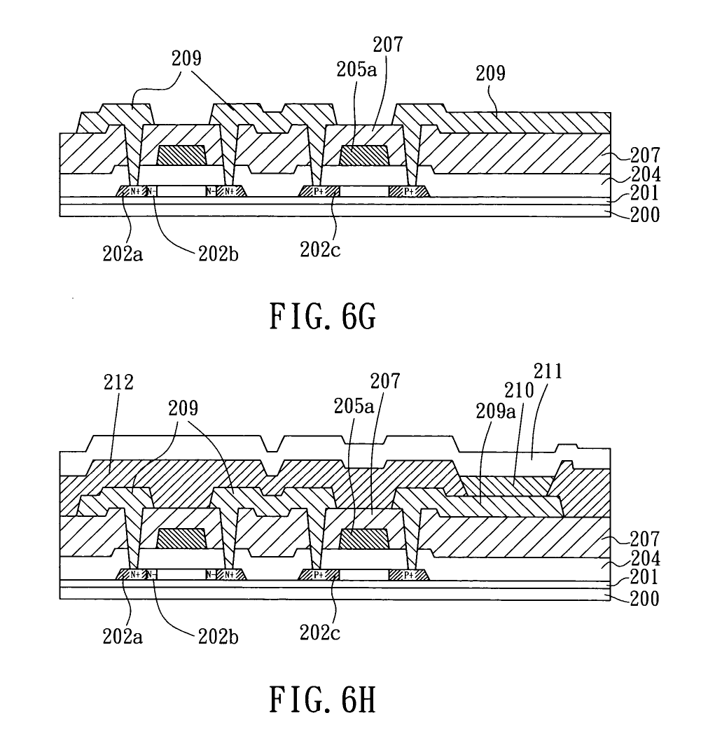

Please refer to FIG. 6A to 6H, which are the schematic illustrations showing the successive procedures for manufacturing a pixel array of a top-emitting OLED driven by CMOS-TFT with accordance to another preferred embodiment of the present invention.

Similar to the aforesaid embodiment, a substrate 200 is provided firstly, and then a passive layer 201 and an amorphous silicon layer are sequentially formed over the substrate 200. Afterward, the processes of laser annealing as well as semiconductor ion implantation and so on are carried out to form poly-silicon, and then the photolithography process is carried out to define at least two poly-silicon islands 202 on the substrate 200 using a first mask, as shown in FIG. 6A. Wherein, the substrate 200 can be made of at least a material selected from the group consisting of glass, plastic, quartz, and silicon crystal.

As shown in FIG. 6B, a photo resist layer 203 is formed over the substrate 200 and then N⁺ implantation areas are defined thereon by a second mask. Wherein, Group V element, such as PH₃ or POCl₃, are implanted into one of the two poly-silicon islands 202 for forming the N⁺ dopant region 202a, as shown in FIG. 6C.

Next, the photo resist 203 is removed, and a gate insulator layer 204 and a metal gate layer 205 are sequentially formed over the substrate 200, and then the gate 205a can be defined by a third mask, as shown in FIG. 6D. Wherein, the gate insulator 204 can be the common insulator material used in semiconductor field, such as SiO₂; and the metal gate layer 205 is made of at least a material selected from the group consisting of Nd, Al, Cr, Mo, Cu, and their alloys.

The following step is a key step of the present invention. A self-alignment implantation of N⁻ is carried out for defining the N⁻ region 202b. Wherein, the dopants can be PH₃, as shown in FIG. 6D.

Afterward, the areas preserved for the P-type devices are defined by a fourth mask enabling the photo resist 206 only to cover the areas preserved for the N-type devices while implanting P⁺ dopants into the other poly-silicon island 202 so as to form P⁺ dopant region 202c. Obviously, in the process of implantation, photo resist 206 only covers the preservation areas of N-type devices so that the other areas will carry out the self-alignment process, gaining the higher process margin more than that in the conventional method. This is also the key point of the present invention, as shown in FIG. 6E.

As shown in FIG. 6F, photo resist 206 is removed and an inter-layer dielectric (ILD) layer 207 is formed, and then a plurality of contact holes 208 is etched to the top of the poly-silicon island 202 which is defined by a fifth mask. Wherein, the material of ILD layer 207 can be any kind of the organic or inorganic insulator material such as SiOx and SiNx.

The following step is a key step of the present invention. A source/drain metal layer is formed and then a source/drain 107 is patterned thereon by a six mask. Wherein, the source/drain metal layer is extended to the pixel area of the top-emitting OLED or employing the same as the bottom electrode 209a of the top-emitting OLED. Thus the processes for manufacturing a CMOS-TFT for driving pixel array of a top-emitting OLED are completed by using only six masks, which is three-mask less comparing to the nine-mask process of the conventional method. By virtue of this, the present invention largely simplifying the process and thus saving the manufacturing cost.

Afterward, a passive layer 211 is formed on the portion areas over the ILD layer 207 for the purpose of preventing shorting between the top and bottom electrodes in OLED. Then an organic emissive layer (EML) 210 and a top electrode 211 are sequentially formed over the bottom electrode 209a of source/drain metal layer. Thus, the bottom electrode 209a, the organic emissive layer 210, and the top electrode 211 constitute a top-emitting OLED.

Wherein, the organic emissive layer 210 can be of any organic emissive materials used in normal OLED, such as small molecule organic dye with high emitting efficiency like Alq3, and organic polymer like PPV, and so on. Moreover, for the purpose of top-emitting OLED, the material of top electrode 211 must be made of a transparent material, such as indium tin oxide (ITO) and indium zinc oxide (IZO).

Consequently, the top-emitting OLED pixel driven either by P-type thin film transistor or CMOS transistors according to the present invention can largely reduce the usage of mask in the manufacturing process, since both embodiments employ the source/drain metal layer of the either transistor, which is extending from the transistor to the pixel area of the top-emitting OLED, as the bottom electrode of the OLED.

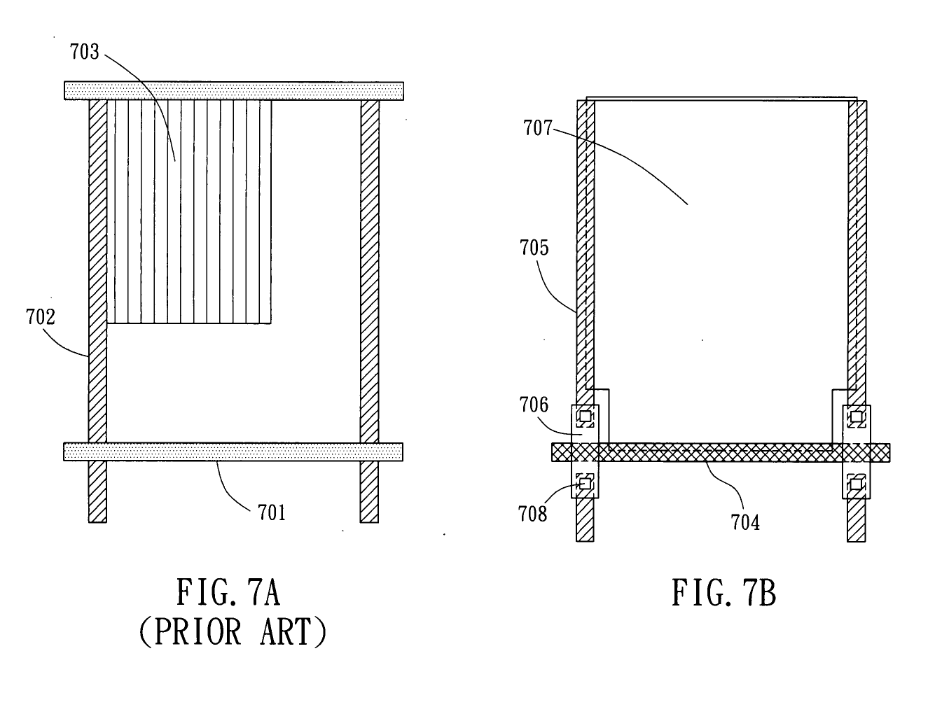

Besides, the method of the present invention applied in the conventional pixel design will result in the problem of aperture ratio descending, as shown in FIG. 7A. Wherein, the scan metal lines 701 and the data metal lines 702 are respectively made from the first and the second metal layer. Therefore, if the data metal lines 702 and pixel electrodes 703 are made from the second metal layer simultaneously, they must be separated with a certain space for preventing shorting and thus limiting the size of the pixel electrodes 703. However, the present invention also provides a new pixel design being able to increase the aperture ratio. As shown in the FIG. 7B, most of the scan metal lines 704 and data metal lines 705 are located in the first metal layer. Only when the data metal lines 705 needs to cross the scan metal lines 704, they will connected to the second metal layer through the contact holes 708 and joint with the connecting lines 706 located in the second metal layer, and thus the pixel electrodes 707 made from the second metal layer can overlap most of the scan metal lines 704 and data metal lines 705, that increase the aperture ratio.

The process for manufacturing a pixel array of a top-emitting OLED according to the present invention has the following advantages:
1. The present invention integrates the second metal layer of the thin film transistor with a top-emitting OLED, i.e. the source/drain metal layer is being employed as the bottom electrode of the OLED, for applying the top-emitting OLED in a top-emitting OLED display. In this regard, the present invention provide a pixel array top-emitting OLED, which can function not only without the ITO layer used in a convention OLED for inputting electron holes and downward-transmitting light, but also without the insulator layer along with the contact hole arranged thereon which are sandwiched between the second metal layer and the ITO layer.
2. The method of the present invention can save at least 2 masks in comparison withthat of the conventional thin film transistor process and thus being able to reduce the manufacturing cost.
3. The present invention can simplify the process and provide more layout spaces and thus raise the layout density and reduce manufacturing cost so as to improve the product competitiveness.
4. The present invention can be easily realized by those skilled in the art. It neither requires complex process, nor largely changes the present equipments. Moreover, the reliability of the present invention is better than that of the prior art.

In summary that this invention has been disclosed and illustrated with reference to particular embodiments, the principles involved are susceptible for use in numerous other embodiments that will be apparent to persons skilled in the art. Consequently, the present invention has been examined to be progressive and has great potential in commercial applications.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

1. A method for manufacturing a pixel array of a top-emitting organic light emitting diode (OLED), comprising:
providing a substrate, having at least two poly-silicon islands defined thereon;
defining an N+ implantation region on said substrate;
forming a gate insulator layer and a gate metal layer sequentially, and then defining a gate;
carrying out an− implantation for forming the light doped drain (LDD) region;
forming a photo resist layer to cover designated areas for N-type device, and expose designated areas for P-type device for carrying out an P+ implantation;
forming an inter-layer dielectric (ILD) layer and etching a plurality of contact holes thereon; and
forming a source/drain metal layer and defining a source/drain pattern thereon; wherein said patterned source/drain metal layer extends to the pixel array of said top-emitting OLED so as to be employed as a bottom electrode of said top-emitting OLED.

2. The method as recited in claim 1, further comprising:
forming a organic emissive layer and a top electrodes sequentially on said source/drain metal layer employed as said bottom electrode of said top-emitting OLED.

3. The method as recited in claim 1, further comprising:
forming a passive layer over said ILD layer.

4. The method as recited in claim 1, wherein the step of said N− implantation for forming the LDD region is substantially a process of self-alignment implantation.

5. The method as recited in claim 1, wherein the step of said P+ implantation is substantially a process of self-alignment implantation.

6. The method as recited in claim 1, wherein said substrate is made of a material selected from the group consisting of glass, plastic, quartz, and silicon crystal.

7. The method as recited in claim 1, wherein said gate metal layer is made of at least a material selected from the group consisting of Nd, Al, Cr, Mo, Cu, and their alloys.

8. The method as recited in claim 1, wherein said source/drain metal layer is made of at least a material selected from the group consisting of Nd, Al, Cr, Mo, Cu, and their alloys.

9. A method for manufacturing a pixel array of a top-emitting organic light emitting diode (OLED), comprising:
providing a substrate, having at least a poly-silicon island defined thereon;
forming a gate insulator layer and a gate metal layer sequentially, and then defining a gate;
carrying out a P+ implantation;
forming an inter-layer dielectric (ILD) layer and etching a plurality of contact holes thereon; and
forming a source/drain metal layer and defining a source/drain pattern thereon; wherein said patterned source/drain metal layer extends to the pixel array of said top-emitting OLED so as to be employed as a bottom electrode of said top-emitting OLED.

10. The method as in claim 9, further comprising:
forming a organic emissive layer and a top electrodes sequentially on said source/drain metal layer employed as said bottom electrode of said top-emitting OLED.

11. The method as recited in claim 9, further comprising:
forming a passive layer over said ILD layer.

12. The method as recited in claim 9, wherein the step of said P+ implantation is substantially a process of self-alignment implantation.

13. The method as recited in claim 9, wherein said substrate is made of a material selected from the group consisting of glass, plastic, quartz, and silicon crystal.

14. The method as recited in claim 9, wherein said gate metal layer is made of at least a material selected from the group consisting of Nd, Al, Cr, Mo, Cu, and their alloys.

15. The method as recited in claim 9, wherein said source/drain metal layer is made of at least a material selected from the group consisting of Nd, Al, Cr, Mo. Cu, and their alloys.

16. A structure of top-emitting OLED pixel, comprising:
a top-emitting OLED, further comprising a top electrode, and organic emissive layer, and a bottom electrode;
a thin film transistor for driving the top-emitting OLED, further comprising at least a source/drain metal layer patterned with at least a source/drain;
wherein, the bottom electrode is substantially-the portion of the source/drain extending from the source/drain metal layer to the pixel area of the top-emitting OLED.

17. The structure as recited in claim 16, wherein said source/drain metal layer is made of at least a material selected from the group consisting of Nd, Al, Cr, Mo, Cu, and their alloys.
